(19) United States
(12) Patent Application Publication
(10) Pub. No.: US 2011/0291144 A1
(43) Pub. Date: Dec. 1, 2011

(54) OPTICAL SEMICONDUCTOR DEVICE

(75) Inventors: Kyohiro Yoshida, Osaka-shi (JP); Takeshi Okada, Osaka-shi (JP)

(73) Assignee: SUMITOMO ELECTRIC INDUSTRIES, LTD., Osaka-shi (JP)

(21) Appl. No.: 13/148,248

(22) PCT Filed: Feb. 22, 2010
(86) PCT No.: PCT/JP2010/052614

§ 371 Date: Aug. 5, 2011

(30) Foreign Application Priority Data
Feb. 25, 2009 (JP) 2009-042554

(51) Int. Cl. H01L 33/58; H01L 31/0232

(52) U.S. Cl. 257/98; 257/432; 257/E33.073; 257/E31.127

(57) ABSTRACT

A semiconductor optical module M is disclosed, where it includes a stem 2 that installing electronic components 1, a lead pin 3, a circular cap 10, and a lens 5 assembled within the cap 10; and has a flange 12 for welding in an end of the cap 10 opposite to the stem 2, the flange radially extending outward. When the cap 10 is welded to the housing A, the cap 10 may be abutted as setting the welding line b nearly equal to the right angle with respect to the flange 12 of the cap, which increases the welding strength. Because the flange does not form any walls of the cap, the loss of the air-tightness due to the welding may be prevented. Moreover, because the flange radially extends outward at the end of the cap, which is apart from the lens 5, the lens may be secured against the damage.

### TECHNICAL FIELD

The present invention relates to an semiconductor optical module that includes a light-receiving device to convert an optical signal into an electrical signal, or a light-transmitting device to convert an electrical signal into an optical signal; and an electronic module including the semiconductor optical module such as a bi-directional optical module for a single fiber.

### BACKGROUND ART

The semiconductor optical module M generally comprises, as shown in FIG. 11, a stem 2 that mounts an semiconductor optical module or electronic components including the semiconductor optical module thereon; lead pins 3 extended from the stem 2 and connected to the semiconductor optical module or the electronic components including the semiconductor optical module; a cap 4 welded and fixed to the stem 2 so as to cover the semiconductor optical module or the electronic components including the semiconductor optical module; and a lens 5 assembled within the cap 4.

The semiconductor optical module M, when it is a light-receiving module installing the light-receiving device as the semiconductor optical device, outputs an electrical signal through the lead pin 3 directly or indirectly through electronic components 1 for an electronic circuit, where the electrical signal is converted from an optical signal transmitted from an optical fiber B (refer to FIG. 1) and received by the light-receiving device such as photodiode through the lens 5. When the semiconductor optical module M is a light-transmitting module installing the light-transmitting device as the semiconductor optical device, an optical signal, which is converted from an electrical signal provided from the lead pin directly or indirectly through electronic components for an electronic circuit, is output to the optical fiber through the lens 5 and transmitted externally through the optical fiber B.

When the semiconductor optical module M is applied to a bi-directional optical module for the single fiber, as shown in FIG. 11, one installs the semiconductor optical module M by welding and fixing the cap 4 to the housing A thereof.

The fixing by the weld is generally carried out (refer to patent documents 1 and 2 below) by welding an end of the cap 4 (a symbol “a” denotes a point to be welded in the figure).

### PRIOR ARTS

### Patent Documents

Patent document 1 Japanese Patent published as 2003-241029A

Patent document 2 Japanese Patent published as 2005-217074A

### DISCLOSURE OF INVENTION

### Subjects to be Solved by Invention

It is preferable in the welding of the cap 4 by the end portion thereof that the YAG laser beam b irradiates the point “a” from a direction of the center axis of the semiconductor optical module M as close as possible from a viewpoint of obtaining the bonding strength (welding strength).

However, the conventional cap 4, as shown in FIG. 11, has a cylindrical shape with a substantial uniform radius, which sometimes causes a lack of enough welding strength such as, depending on the shape of the housing A, a lesser gap between the outer surface of the cap 4 and the outer wall of the housing A (refer to a step appeared in a neighborhood of the fixed point of the light-receiving module M1 to the housing A shown in FIG. 1), or the outer surface of the cap 4 interferes the welding machine, which forces the YAG laser beam b to be further inclined as illustrated in a chain line.

Moreover, the point a to be welded is a wall of the cap which air-tightly seals the semiconductor optical module or the components for an electronic circuits 1 including the semiconductor optical module; accordingly, the welding sometimes breaks the wall, which results in the breakage of the air-tightness. In particular, when the laser beam b becomes further inclined as illustrated in the chain line in FIG. 11, a substantial portion of the laser beam is irradiated on the wall, which causes the increase of the possibility of the breakage of the air-tightness. A product with less air-tightness becomes inferior goods.

In addition, the cap 4 is conventionally formed by the machining, which increases the production cost. In order to suppress the machining cost, the convention cap 4 provides a flange 4a in an inner side of the end portion thereof, as shown in FIG. 11, to support the lens 5. This arrangement exposes the lens 5 from the cap 4, which may not only damage the lens 5 mechanically but possibly damage the lens 5 and the seal glass to fix the lens 5 by the laser beam b because of their closer arrangement to the welded point a.

Taking the present status described above into consideration, the present invention has following subjects to be solved: to realize an increase bonding strength without degrading the air-tightness within the cap 4 and damaging the lens 5 accompanied with other components by the welding.

### Means to Solve Subjects

The present invention, to overcome the subject above mentioned, the cap 4 has a flange radially extending outward in the end thereof. Because of the flange radially extending outward in the end of the cap, the welding line b, for instance, the beam line of the YAG laser, may be set nearly equal to the right angle with respect to the flange, which may increase the welding strength.

Moreover, the flange does not constitute any walls of the cap to enclose the electronic components air-tightly and the welded portion in the flange may be apart from the sealed portion; accordingly, the air-tightness maybe escaped from the breakage even when the welding causes a hole in the flange. Further, the welded portion in the flange positions at points radially heading outward in the end of the cap, which is apart from the lens and the glass to fix the lens; accordingly, the damage on the lens caused by the welding may be escaped. As a result, the accuracy of the alignment of the point irradiated by the laser may be relaxed.

The structure of the present invention comprises a stem that mounts a semiconductor optical device or electronic components including the semiconductor optical devices, a lead pin protruding from the stem, a cap fixed to the stem so as to cover the semiconductor optical device or the electronic components including the semiconductor optical device, a lens installed with the cap, wherein the cap has a flange for welding in a end for welding opposite to the stem, and the flange radially extends outward. The radially outward means a direction extending outward from a center axis of the cap.

The lens, same as those in a conventional one, may protrude from the cap; but, by positioning the lens so as not to extrude from the opening in the end for welding opposite to the stem, the lens may be escaped from damage by coming in contact with other components because the lens does not protrude from the cap.

The shape of the cap is an optional, not restricted to a substantially cylindrical shape similar to those in a conventional one, as far as it not only installs the semiconductor optical device or the electronic components 1 including the semiconductor optical device and lens 2 but shows the converting function from optical to electrical; and a polygonal tube such as square shape may be applicable. The cap, by including the choked portion from the end fixed to the stem to the flange for welding, may make the semiconductor optical module in compact because the size of the cap may be decreased by narrowing the flange inward by the choked portion.

The choking degree may be optional depending on the design. However, setting the choking angle θ in 45°, refer to FIG. 2, the welding line b of the YAG laser may make an angle of 45° with respect to the flange. The welding line b, when it makes the angle α of nearly equal to 90°, results in the strongest welding; while, the angle α of 45° is the minimum angle to realize the minimum required strength. A smaller choked angle θ(45°>θ) sets the side wall of the cap in nearly right angle with respect to the flange, which makes the welding line b hard to show an enough angle α (>45°); on the other hand, a greater choked angle θ (45°<θ) makes the size of the cap small, which brings subjects for installing components like lens 5 and sealing air-tightly.

Moreover, the cap may have the choked portion extending in a whole side wall thereof, or restricted up to the halfway thereof (refer to FIG. 5), have a composite shape of a cylinder with a length from the fixed end to the stem with a choked portion, or this choked portion is up to the halfway thereof (refer to FIG. 2). Thus, the shape of the choked portion is optional as far as the function and the result of the invention may be secured.

The lens 5 is supported by the inner surface of the choked portion, where the inner surface supporting it may have a cylindrical shape (refer to FIGS. 2 and 5). The cylindrical supporting surface may not only facilitate the glass sealing of the lens 5 but stably set the lens. Moreover, the lens 5 is preferable to be glass-sealed from the side of the stem 2. Because the flange 12 is apart from the portion to be glass-sealed, the air-tightness is hard to be broken at the welding of the flange.

The cap may be formed by machining as conventional, but preferable to be formed by stamping from cost effectiveness because the shape of the flange radially extending outward is easily formed by stamping.

Thus, the semiconductor optical module with arrangements above described may be applicable to those electronic modules to which a conventional semiconductor optical module is also applied, for instance, to the bi-directional optical module for the single fiber.

### Results of Invention

The present invention, as described above, provides a flange for the welding, which results in the enhanced boding strength without degrading the air-tightness in the cap, and damaging the lens and other components.

### BRIEF DESCRIPTION OF DRAWINGS

FIG. 1 is a perspective view showing an semiconductor optical module according to an embodiment of the invention;

FIG. 2 is a cross section of a primary portion of the semiconductor optical module shown in FIG. 1;

FIG. 3 magnifies a portion of FIG. 2;

FIG. 4 is a perspective view showing the semiconductor optical module;

FIG. 5 is a cross section of a primary portion of an semiconductor optical module according to another embodiment of the invention;

FIG. 6 is a cross section of a primary portion of an semiconductor optical module according to still another embodiment of the invention;

FIG. 7 is a perspective view showing an module implemented with the semiconductor optical module;

FIG. 8 is a perspective view showing another module implemented with the semiconductor optical module;

FIG. 9 is a perspective view showing still another module implemented with the semiconductor optical module;

FIG. 10 is a perspective view showing still another module implemented with the semiconductor optical module; and

FIG. 11 is a cross section of a primary portion of a conventional semiconductor optical module.

### DESCRIPTION OF SYMBOLS

1: semiconductor optical module or electronic component including the semiconductor optical module;

2: stem

3: lead pin

4, 10: cap

5: lens

11: flange in the side of the stem

12: flange in the housing side (flange for welding)

14: cap body

14a, 14c: cylindrical portion of the cap body

14b: choked portion of the cap body (truncated cone portion)

15: end opening in a side to be welded in the cap

A: housing

M: semiconductor optical module

M1: light-receiving module

M2: light-transmitting module

a: point to be welded

b: YAG laser beam (welding line)

α: irradiating angle of welding line

θ: choked angle

### BEST MODE TO PERFORM INVENTION

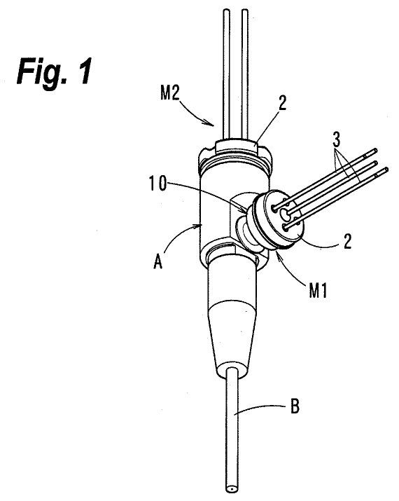

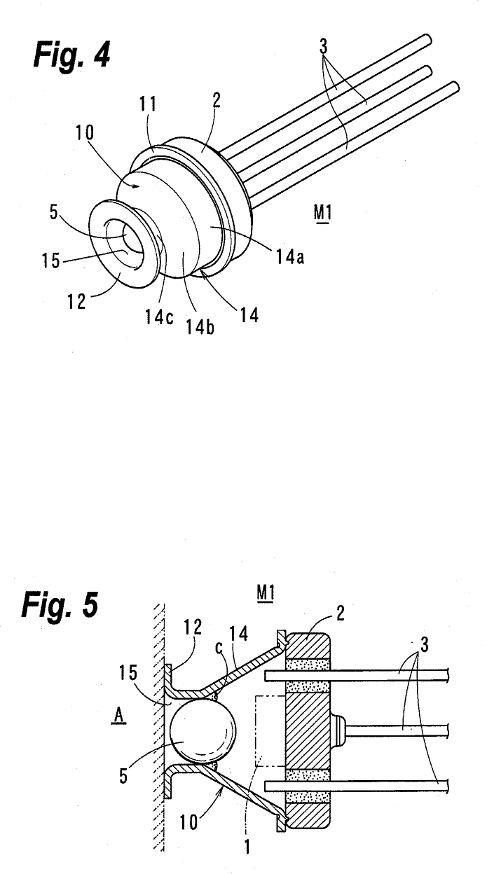

FIGS. 1 to 4 show an embodiment of a bi-directional optical module for the single fiber that installs a light-receiving module M1 according to the present invention and a conventional light-transmitting module M2, which may be applicable to, for to instance, a di-plexer. The light-receiving module M1 and the light-transmitting module M2 include a stem 2 that mounts a semiconductor optical device or components for an electronic circuit including a semiconductor optical device, lead pins 3 extending from the stem 2, a cap 10 fixed to the stem 2 by the welding so as to cover the semiconductor optical device or the components 1 for an electronic circuit including the semiconductor optical device, and a lens 5 assembled in the cap 10; where the arrangement of these components is similar to those in a conventional optical module, and are made of similar material and formed in similar form except for the cap 10 of the light-receiving module M1.

The semiconductor optical device in the light-receiving module M1 may be a PIN photodiode, an avalanche photodiode and so an; further for electronic components, pre-amplifiers, die-capacitors, resistors, and inductors in addition to the semiconductor optical device may be used as occasion demands. The semiconductor optical device in the light-transmitting module M2 may be a semiconductor laser diode, a light-emitting diode (LED), and so on; while for electronic components, a driver circuit, die-capacitors, resistors, inductors and so an in addition to he semiconductor optical device may be used as occasion demands. The light-transmitting module M2 is attached to the housing A in a form similar to those illustrated in FIG. 3 of the first patent document.

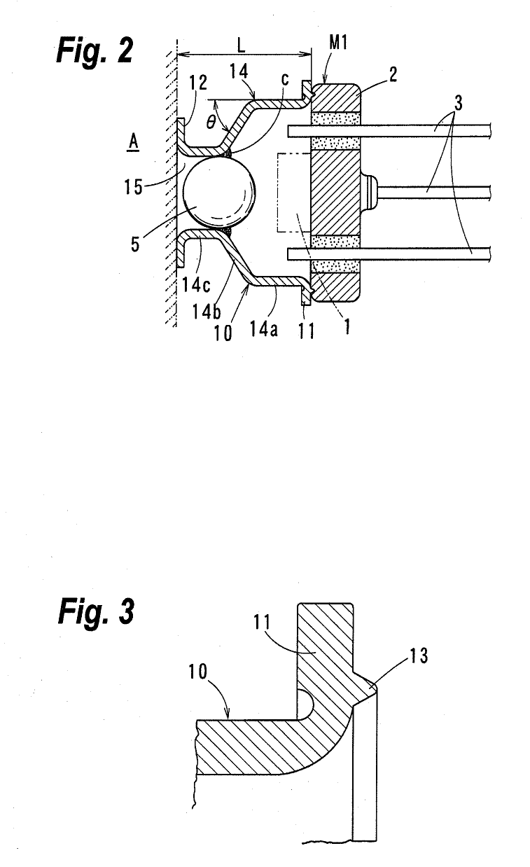

The cap 10 of the light-receiving module M1 may be formed by the press-forming of stainless steel with a thickness of 0.2 mm and incldues flanges, 11 and 12, extending outwardly along the radial direction from the whole circumference at both ends thereof. The flange 11 fixed to the stem 2 has the outer diameter of 4.7 mm and the inner diameter of 3.5 mm; and has a rib 13 with a triangular cross section in the whole circumference of the outer surface thereof (the surface facing the stem 2), as illustrated in FIG. 3. Welding the rib 13 to the stem 2, the air-tightness may be secured. The flange 12 welded to the housing A, which is formed in the end of the cap 10 opposite to the stem 2, has the outer diameter of 3.1 mm and the inner diameter of 1.5 mm (the diameter of the aperture 15). The length L of the cap 10, which is the lateral length in FIG. 2, is 2.85 mm.

The body 14 of the cap 10 between the flanges, 11 and 12, has a cylindrical portion 14a extending from one of the flange 11 in the side of the stem 2 to a halfway thereof (a lateral length of which is 1.0 mm in FIG. 2), a choked portion 14b with a shape of a truncated cone extending from the halfway, an choked angle θ of which is 45° (a lateral length of 0.75±0.02 mm), and another cylindrical portion 14c extending to the other flange 12 of the housing A.

The other cylindrical portion 14c of the cap 10 supports the lens 5 by a low-melting glass. The lens 5 positions inward from the end opening 15 of the other flange so as not to protrude from the end opening 15. The low-melting glass c (refer to FIG. 2) is put between the lens 5 and the cap 10 from the side of the stem 2 as a glass pre-form, and may seal them, 5 and 10, by heating and melting it.

The light-receiving module M1 thus configured may be welded to the housing A by irradiating the flange 12 with the YAG laser beam b.

The bi-directional optical module for the single fiber, same as conventional modules, the light-receiving module M1 may output an electrical signal from the lead pin 3 directly or indirectly through another electronic components 1, where the electrical signal is converted from an optical signal entering therein from the optical fiber B and illuminating the light-receiving device through the lens 15; while, the light-transmitting module M2 may output optical signal to the optical fiber B through the lens 5 and externally transmitted through the optical fiber B, where the optical signal may be converted from an electrical signal entering directly or indirectly through another electronic components 1 from the lead pin 3.

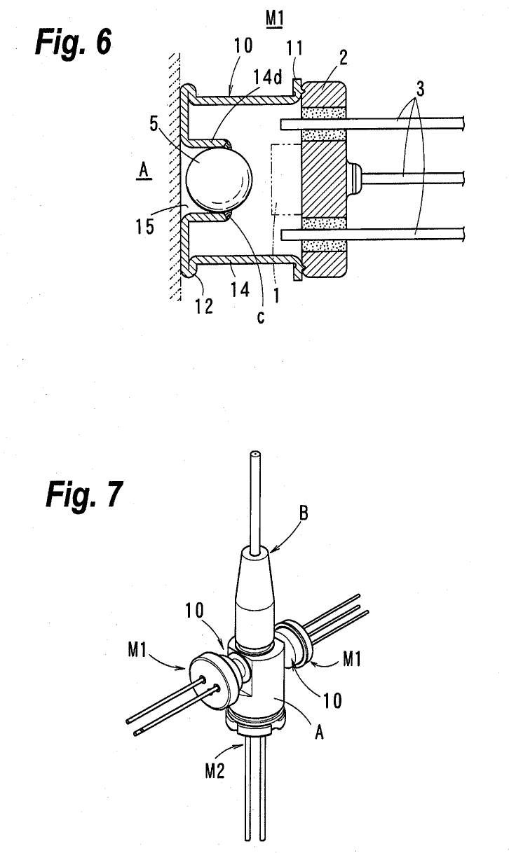

The arrangement of the cap 10 in the light-receiving module M1, in particular, the body 14 thereof may have the cylindrical portion 14a and the choked portion 14b continuous from the cylindrical portion 14a (the choked portion 14b may be comprised of a cylindrical portion 14a and a truncated cone portion 14b), as illustrate in FIG. 5, or may have no choked portion 14b, as shown in FIG. 6. The arrangement shown in FIG. 5 may be further modified such that the other cylindrical portion 14c may have a truncated cone shape (two cylindrical portions, 14a and 14c, and the truncated cone portion 14b constitutes a choked portion). The arrangement illustrated in FIG. 6 folds the flange 12 to form an inner cylindrical portion 14d to support the lens 15.

The cap for the light-transmitting module M2 may have arrangements described above for the cap 10 of the light-receiving module M1.

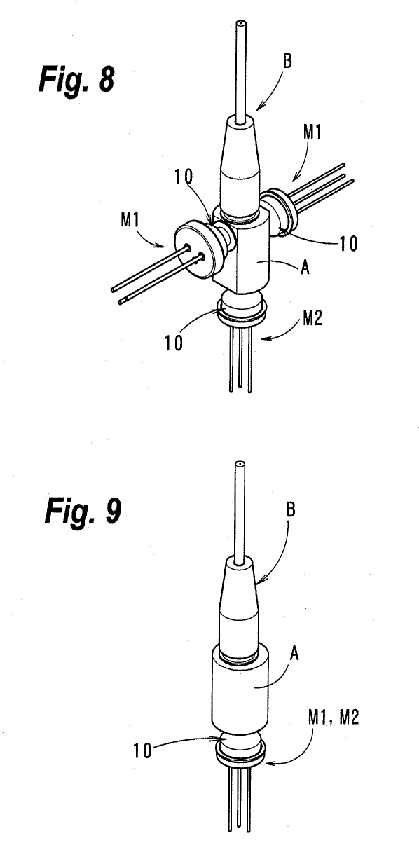

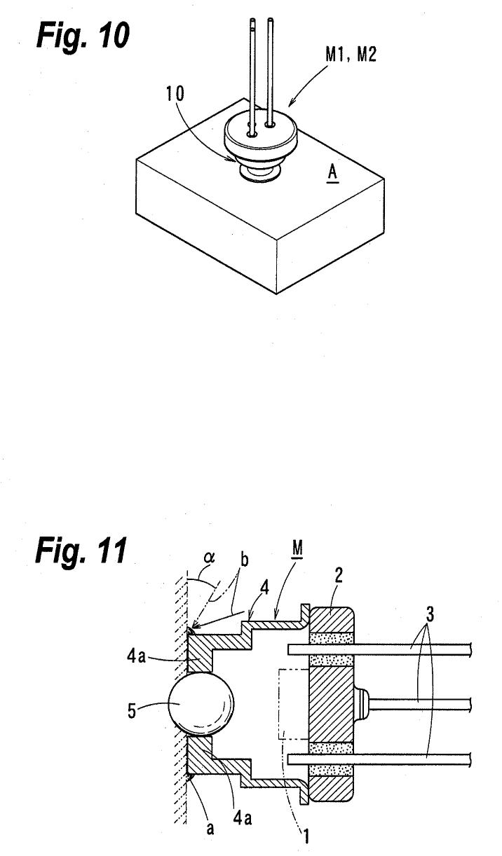

The semiconductor optical module M with various arrangements, unrestricted to the bi-directional module for the single fiber shown in FIG. 1, may be applicable to various modules such as a triplexer bi-directional module for the single fiber shown in FIGS. 7 and 8, a unidirectional module for the single fiber shown in FIG. 9, a bi-directional module for multi fibers, a unidirectional module for multi fibers, and other electronic components including an optical module with a box shaped housing shown in FIG. 10.

The welding means, at far as they show the functions and results of the present invention, is not restricted to the YAG-laser welding in a range such other means do not show the functions and the results inconsistent with the present invention.

Thus, the optical module M of the present invention may have many other modifications and changes may be made thereto, and the embodiments disclosed herein should be construed only as exemplary examples of the invention. It will be apparent that the true scope of the present invention encompasses various other modifications covered by the claims and equivalents thereof.

1. A semiconductor optical module, comprising:
a stem (2) that mounts an semiconductor optical device or electronic components (1) including the semiconductor optical device thereon;
a lead pin (3) protruding from the stem (2);
a cap (10) fixed to the stem (2), the cap covering the semiconductor optical device or the electronic components including the semiconductor optical device; and
a lens (5) assembled within the cap (10),
characterized in that
the cap (10) includes a flange (12) in an end thereof for welding in as side opposite to the stem (2), the flange (12) radially extending outward.

2. The semiconductor optical module of claim 1,
wherein the cap (10) includes a choked portion (14b) from an end fixed to the stem (2) to the flange (12) for welding.

3. The semiconductor optical module of claim 2,
wherein the choked portion (14b) has a choked angle (θ) of 45°.

4. The semiconductor optical module of claim 1,
herein the lens (5) positions without protruding from an end opening (15) formed in the end for welding of the cap (10).

5. The semiconductor optical module of claim 4,
wherein the cap (10) includes a choked portion; and
wherein the lens (5) is supported by an inner surface of the choked portion of the cap (10).

6. The semiconductor optical module of claim 1,
wherein the lens (5) is glass-sealed to the cap (10) from a side of the stem.

7. The semiconductor optical module of claim 1,
wherein the cap (10) is formed by stamping.

8. A bi-directional optical module for a single optical fiber including the semiconductor optical module (M) claimed in claim 1.
